(19) United States
(12) Patent Application Publication
(10) Pub. No.: US 2019/0081077 A1
(43) Pub. Date: Mar. 14, 2019

(54) ACTIVE MATRIX SUBSTRATE

(71) Applicant: Sharp Kabushiki Kaisha, Sakai City, Osaka (JP)

(72) Inventors: Masahiko SUZUKI, Sakai City (JP); Tetsuo KIKUCHI, Sakai City (JP); Hajime IMAI, Sakai City (JP); Hisao OCHI, Sakai City (JP); Hideki KITAGAWA, Sakai City (JP); Setsuji NISHIMIYA, Sakai City (JP); Toshikatsu ITOH, Sakai City (JP); Teruyuki UEDA, Sakai City (JP); Ryosuke GUNJI, Sakai City (JP); Kengo HARA, Sakai City (JP); Tohru DAITOH, Sakai City (JP)

(21) Appl. No.: 16/084,568

(22) PCT Filed: Mar. 13, 2017
(86) PCT No.: PCT/JP2017/009972

§ 371 Date: Sep. 13, 2018

(30) Foreign Application Priority Data
Mar. 15, 2016 (JP) 2016-050859

(51) Int. Cl. H01L 27/12; H01L 29/417; H01L 29/423

(52) U.S. Cl. CPC H01L 27/124; H01L 27/1225; H01L 29/78633; H01L 29/42384; H01L 29/41733

(57) ABSTRACT

An active matrix substrate includes a substrate, a TFT-containing layer which is supported on the substrate, and which includes a gate electrode, a gate insulating layer, a semiconductor layer, and source and drain electrodes of the TFT, a metal wiring layer which is supported on the substrate and has a thickness of 400 nm or more, and an inorganic insulating layer which is thinner than the metal wiring layer, and is arranged on a substrate side of the metal wiring layer and is in contact with a lower surface of the metal wiring layer. The metal wiring layer has tensile stress and the inorganic insulating layer has compressive stress, and a ratio Sb/Sa of an absolute value Sb of a stress value of the inorganic insulating layer to an absolute value Sa of a stress value of the metal wiring layer is 0.6 or more and 1.7 or less.

### TECHNICAL FIELD

The present invention relates to an active matrix substrate.

### BACKGROUND ART

Display apparatuses provided with an active matrix substrate in which switching elements are provided for pixels are widely used. The active matrix substrate includes a thin film transistor (referred to below as “TFT”) as a switching element. In the present specification, a portion of an active matrix substrate corresponding to a pixel of a display apparatus may be referred to as a pixel or a pixel region. Using an oxide semiconductor has also been proposed as the material of the active layer of the TFT instead of amorphous silicon or polycrystalline silicon.

In general, an active matrix substrate is provided with, on an insulating substrate (support substrate) such as a glass substrate, a TFT, a pixel electrode, a source wire connected to a source electrode of the TFT, and a gate wire connected to a gate electrode of the TFT. The source wire is, for example, a metal wire formed using the same conductive film as the source electrode of the TFT, and the gate wire is, for example, a metal wire formed using the same conductive film as the gate electrode. Here, the source wire or the gate wire may be formed using a metal film different from the source electrode or the gate electrode of the TFT (for example, PTLs 1 and 2). Moreover, in addition to the source wire and the gate wire, further metal wires may be provided for various purposes on the active matrix substrate.

### CITATION LIST

### Patent Literature

PTL 1: Japanese Unexamined Patent Application Publication No. 2005-45017

PTL 2: Japanese Unexamined Patent Application Publication No. 2009-295908

### SUMMARY OF INVENTION

### Technical Problem

From the viewpoint of increasing the size and increasing the definition of display apparatuses, there is a need to lower the resistance of the metal wire. In the related art, the thickness of the metal wire is 300 nm or less, but in order to form a wire with lower resistance, there is a need to form a metal wire thicker than in the related art.

The metal wire is generally formed by depositing a metal film over the entire surface of the glass substrate and then patterning the metal film. However, when a comparatively thick metal film (thickness: 500 nm or more, for example) is formed on the glass substrate, warping occurs in the glass substrate due to the tensile stress of the metal film, and the end portions of the glass substrate may float. In the present specification, the extent of the floating of each of the end portions of the glass substrate is referred to as a “warping amount”. When the substrate on which the metal film is formed is arranged on a flat surface, the warping amount refers to the maximum value of the difference between the lower surface of the end portion of the substrate and the flat surface.

In particular, the thinning of glass substrates has progressed in recent years and, when a metal wire thicker than in the related art is formed on a thin glass substrate (thickness: for example, 0.7 mm or less), greater warping may occur.

When warping occurs in the glass substrate, there is a problem in that vacuum adsorption to a stage in a photolithography step for patterning the metal film is not possible. Due to this, it is not possible to obtain a desired wiring pattern. Additionally, since the edge of the glass substrate floats from the stage of a transfer apparatus, there is a possibility that transport failures may occur and mass productivity may decrease. The same problem may occur even in a case where another insulating substrate is used as a support substrate.

An embodiment of the present invention was made in consideration of the above and has an object of suppressing the occurrence of warping caused by a metal wiring layer in an active matrix substrate.

### Solution to Problem

An active matrix substrate according to one embodiment of the present invention has a display region including a plurality of pixels, each of the plurality of pixels having a TFT and a pixel electrode, the active matrix substrate including a substrate, a TFT-containing layer which is supported on the substrate, and which includes a gate electrode, a gate insulating layer, a semiconductor layer, and source and drain electrodes of the TFT, a metal wiring layer which is supported on the substrate and has a thickness of 400 nm or more, and an inorganic insulating layer which is thinner than the metal wiring layer, and is arranged on a substrate side of the metal wiring layer and is in contact with a lower surface of the metal wiring layer, in which the metal wiring layer has tensile stress and the inorganic insulating layer has compressive stress, and a ratio of an absolute value Sb to an absolute value Sa is 0.6 or more and 1.7 or less, the absolute value Sb being a stress value of the inorganic insulating layer, the absolute value Sa being a stress value of the metal wiring layer.

In a certain embodiment, the ratio of the absolute value Sb to the absolute value Sa is 0.7 or more and 1.5 or less.

In a certain embodiment, a thickness of the metal wiring layer is 500 nm or more.

In a certain embodiment, the metal wiring layer includes a wire or an electrode.

In a certain embodiment, the wire extends to cut across the display region.

In a certain embodiment, the TFT-containing layer includes the metal wiring layer.

In a certain embodiment, the metal wiring layer includes the gate electrode and a gate wire electrically connected to the gate electrode.

In a certain embodiment, the metal wiring layer and the inorganic insulating layer are arranged between the TFT-containing layer and the substrate.

In a certain embodiment, a planarization layer which is arranged between the metal wiring layer and the TFT-containing layer is further included.

In a certain embodiment, the metal wiring layer and the inorganic insulating layer are arranged above the TFT-containing layer.

In a certain embodiment, the metal wiring layer includes a Cu layer or an Al layer.

In a certain embodiment, the metal wiring layer further includes a Ti layer or a Mo layer on the substrate side of the Cu layer or the Al layer.

In a certain embodiment, the inorganic insulating layer includes a silicon nitride layer.

In a certain embodiment, the silicon nitride layer has a thickness of 50 nm or more and 300 nm or less.

In a certain embodiment, the substrate is a glass substrate having a thickness of 0.7 mm or less.

In a certain embodiment, the metal wiring layer is a layer obtained by patterning a metal film deposited on the inorganic insulating layer.

In a certain embodiment, the TFT is a channel-etch type TFT.

In a certain embodiment, the semiconductor layer of the TFT is an oxide semiconductor layer.

In a certain embodiment, the oxide semiconductor layer includes an In-Ga-Zn-O-based semiconductor.

### Advantageous Effects of Invention

According to one embodiment of the present invention, it is possible to suppress the occurrence of warping caused by a metal wiring layer in an active matrix substrate.

### BRIEF DESCRIPTION OF DRAWINGS

FIG. 1 is a schematic cross-sectional view showing a part of an active matrix substrate 100 of a first embodiment.

FIGS. 2(a) and 2(b) are schematic cross-sectional views of a sample substrate 100A of an example and a sample substrate 100B of a comparative example, respectively.

FIG. 3(a) is a schematic perspective view showing the sample substrates 100A and 100B, and FIG. 3(b) is a cross-sectional view for illustrating a warping amount.

FIG. 4 is a diagram showing a relationship between the thickness of a Cu film and the warping amount in the sample substrates 100A and 100B of the example and the comparative example.

FIG. 5 is a diagram showing a relationship between the thickness of an inorganic insulating layer 30 and the warping amount in the sample substrates 100A and 100B of the example and the comparative example.

FIG. 6 is a diagram showing a relationship between a ratio Sb/Sa of an absolute value Sb of compressive stress of the inorganic insulating layer 30 to an absolute value Sa of tensile stress of a metal film 120, and the warping amount (μm).

FIGS. 7(a) to 7(c) are schematic cross-sectional views each illustrating an arrangement relationship between a metal wiring layer 20 and a TFT-containing layer 40 in the present embodiment.

FIG. 8 is a schematic cross-sectional view of an active matrix substrate 101 of a second embodiment.

FIG. 9 is a schematic cross-sectional view of an active matrix substrate 102 of a third embodiment.

FIG. 10 is a schematic cross-sectional view of an active matrix substrate 103 of a fourth embodiment.

### DESCRIPTION OF EMBODIMENTS

### First Embodiment

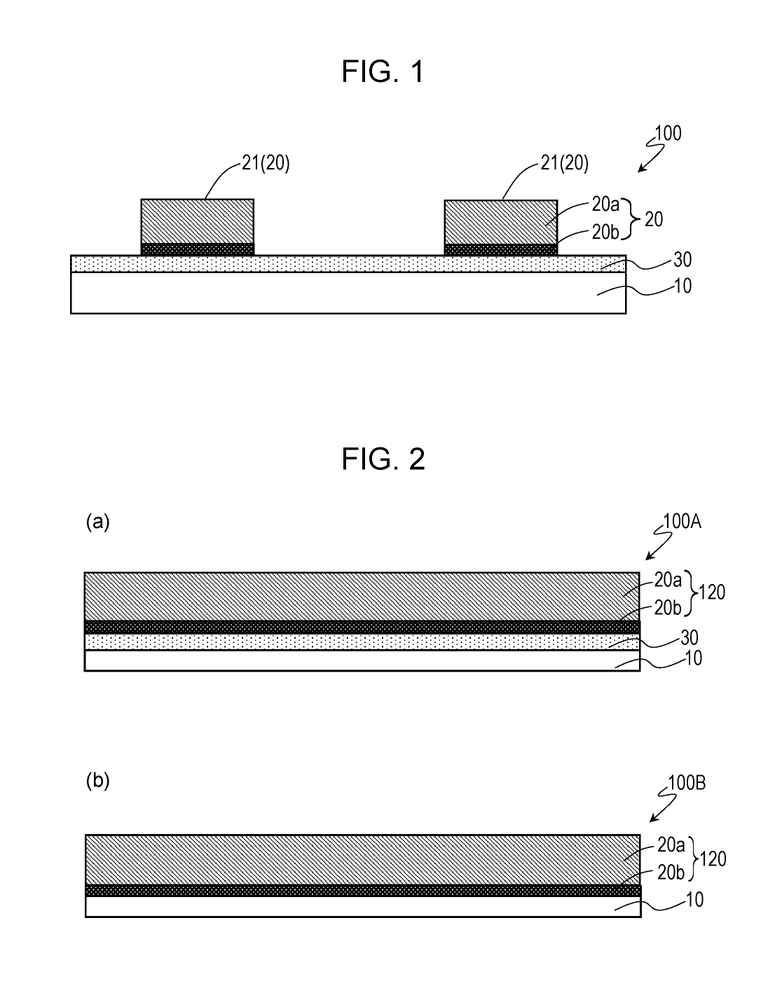

FIG. 1 is a schematic cross-sectional view showing a part of the active matrix substrate 100 of the first embodiment.

The active matrix substrate 100 has a substrate 10, the metal wiring layer 20 supported on the substrate 10, and the inorganic insulating layer (also referred to as a stress relieving layer) 30 formed on the substrate 10 side of the metal wiring layer 20. The inorganic insulating layer 30 is in contact with a lower surface of the metal wiring layer 20. The metal wiring layer 20 is a layer formed using a metal film formed on the inorganic insulating layer 30. In this example, the metal wiring layer 20 includes a plurality of metal wires 21.

Although illustration thereof is omitted, the active matrix substrate 100 is further provided with a TFT, a pixel electrode, an interlayer insulating layer, and the like to be described below. In addition, in FIG. 1, the inorganic insulating layer 30 is in contact with the substrate 10, but there may be another layer between the inorganic insulating layer 30 and the substrate 10.

The substrate 10 is a substrate having an insulating surface. Here, a glass substrate is used as the substrate 10. The thickness of the glass substrate is, for example, 0.57 mm or more and 0.7 mm or less. The thickness of the glass substrate may be 0.4 mm or less.

The inorganic insulating layer 30 may be, for example, a silicon oxide (SiO₂) layer, a silicon nitride (SiNₓ) layer, a silicon oxynitride (SiOₓN_{y}; x>y) layer, a silicon nitride oxide (SiNₓO_{y}; x>y) layer, or a laminated film of the above. In this example, the inorganic insulating layer 30 is a SiNₓ layer. The inorganic insulating layer 30 is preferably thinner than the metal wiring layer 20. The thickness of the inorganic insulating layer 30 is not particularly limited, but may be, for example, 50 nm or more and 300 nm or less, and preferably 100 nm or more and 200 nm or less.

The metal wiring layer 20 is, for example, a layer obtained by patterning a metal film deposited on the inorganic insulating layer 30. The metal wiring layer 20 is formed using a metal film including elements selected from, for example, copper (Cu), aluminum (Al), chromium (Cr), tantalum (Ta), titanium (Ti), molybdenum (Mo), or tungsten (W), an alloy film having these elements as components, or a laminated film including a plurality of these films. The thickness of the metal wiring layer 20 is 400 nm or more, and preferably 500 nm or more. With this, it is possible to form the low-resistance metal wiring layer 20. On the other hand, from the viewpoint of miniaturization of the active matrix substrate 100, the thickness of the metal wiring layer 20 is, for example, 3 μm or less.

In this example, the metal wiring layer 20 includes a first metal film 20a having a comparatively low electric resistance. The first metal film 20a is, for example, a Cu film or an Al film. The thickness of the first metal film 20a is, for example, 500 nm or more. The metal wiring layer 20 may have a laminated structure of the first metal film 20a and another metal film. As shown in the diagrams, the metal wiring layer 20 may have a laminated structure of the first metal film 20a and a second metal film 20b arranged on the substrate 10 side of the first metal film 20a. For example, the second metal film 20b may be a Ti film, a Mo film, or the like. The second metal film 20b may be thinner than the first metal film 20a, for example, 15 nm or more and 75 nm or less.

The metal wire 21 is a low-resistance wire formed in the metal wiring layer 20. The metal wire 21 preferably includes wires extending over a long distance. For example, the metal wire 21 may be a wire extending to cut across a plurality of pixels or to cut across a display region. The metal wire 21 may be a source wire, a gate wire, a common wire, an auxiliary capacitor wire, or the like. Alternatively, the metal wire 21 may be, for example, a detection electrode such as a photosensor or a touch sensor, a driving wire, or the like. Here, in addition to the metal wire 21 or in place of the metal wire 21, an electrode, a light shielding layer, or the like may be formed in the metal wiring layer 20.

In the present embodiment, the metal wiring layer 20 has a tensile stress, and the inorganic insulating layer 30 has a compressive stress. The ratio Sb/Sa of the absolute value Sb of the stress value of the inorganic insulating layer 30 to the absolute value Sa of the stress value of the metal wiring layer 20 is 0.6 or more and 1.7 or less, and preferably 0.7 or more and 1.5 or less. Here, the stress values of the metal wiring layer 20 and the inorganic insulating layer 30 may differ depending not only on the material and thickness of these layers, but also on the process conditions for forming these layers.

Although not illustrated, the active matrix substrate 100 is provided with a layer including a TFT (referred to below as a “TFT-containing layer”) supported on the substrate 10. The TFT-containing layer includes a gate electrode layer including a gate electrode of the TFT, a gate insulating layer, a semiconductor layer including an active layer of the TFT, and a source electrode layer including source and drain electrodes. The metal wiring layer 20 may be a gate electrode layer or a source electrode layer in the TFT-containing layer. For example, in a case of forming a TFT having a bottom gate structure on the substrate 10, the metal wiring layer 20 may be a gate electrode layer. Alternatively, the metal wiring layer 20 may be arranged above or below the TFT-containing layer and may be a different layer from the TFT-containing layer.

As described above, the metal wire 21 is formed, for example, by depositing a metal film over the entire surface of the glass substrate and then patterning the metal film. In the present embodiment, the inorganic insulating layer 30 having a compressive stress is formed on the substrate 10, and a metal film (here, a laminated film of the first metal film 20a and the second metal film 20b) is formed on the inorganic insulating layer 30. Therefore, it is possible for the stress applied to the substrate 10 by the metal film to be relieved by the inorganic insulating layer 30, and it is possible to reduce the warping amount of the substrate 10. The warping amount is reduced to, for example, half or less in comparison with a case where the inorganic insulating layer 30 is not formed.

As described above, according to the present embodiment, forming the inorganic insulating layer 30 having a prescribed compressive stress between the metal wiring layer 20 and the substrate 10 makes it possible to reduce warping of the substrate 10. Accordingly, since it is possible to increase the thickness of the metal wire 21, it is possible to suppress a reduction in yield due to warping of the substrate 10 while realizing low resistance in the metal wire 21.

### EXAMPLES AND COMPARATIVE EXAMPLES

Next, a description will be given of the results of experiments conducted by the present inventors to investigate the effects of the inorganic insulating layer 30.

First, sample substrates of comparative examples and examples were prepared, and the warping amount of each sample substrate was examined.

FIGS. 2(a) and 2(b) are schematic cross-sectional views of the sample substrate 100A of the example and the sample substrate 100B of the comparative example, respectively.

The sample substrate 100A of the example was prepared as follows. First, the inorganic insulating layer 30 was formed on the entire surface of the substrate 10 by a CVD method. As the substrate 10, a 2200×2450 mm alkali-free glass substrate having a thickness of 0.63 mm was used. As the inorganic insulating layer 30, a SiN film having a thickness of 100 nm was formed. Next, on the inorganic insulating layer 30, a Ti film with a thickness of 35 nm and a Cu film with a thickness of 500 nm were formed in this order by a sputtering method to form the metal film 120. A plurality of the sample substrates 100A having different Cu film thicknesses or different insulating layer thicknesses were obtained with the same method.

Additionally, the sample substrate 100B of a comparative example was prepared with the same method as in the example except that the inorganic insulating layer 30 was not formed. In the comparative example, the metal film 120 was formed so as to be in direct contact with the surface of the substrate 10.

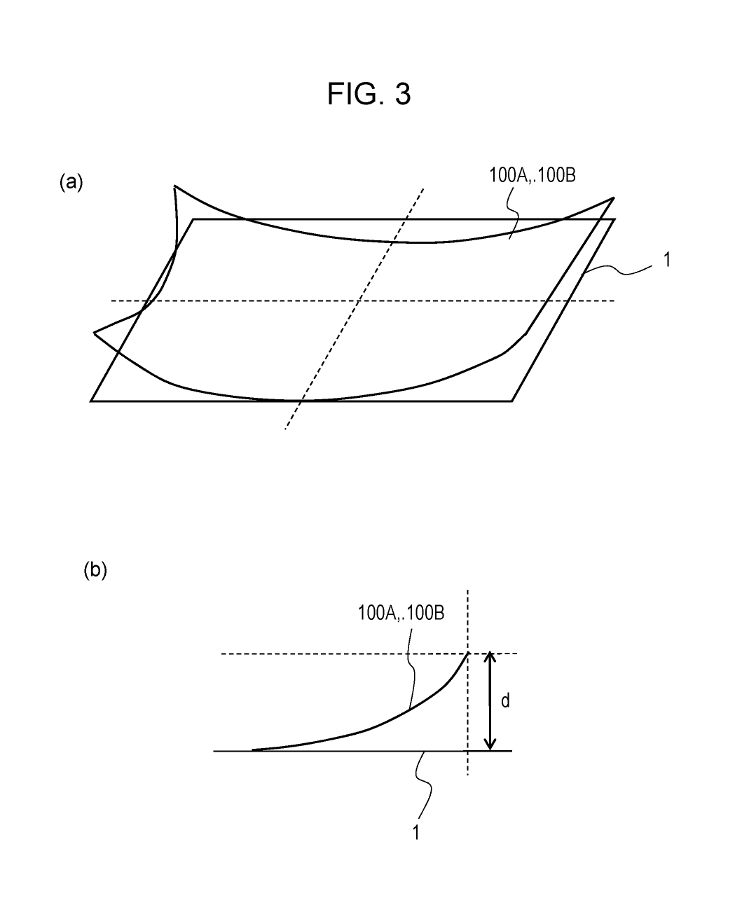

Next, the warping amount of each of the obtained sample substrates 100A and 100B was measured. FIG. 3(a) is a schematic perspective view showing the sample substrates 100A and 100B. When the sample substrates 100A and 100B are placed on a flat surface (here, a stage surface) 1, the warping amount increases at the four corners of the sample substrates 100A and 100B. As shown in FIG. 3(b), the height (maximum value) of the end portion of the substrate 10 from the flat surface 1 was measured and set as a “warping amount d”.

Here, in all the examples and comparative examples, since there is a Ti film (sufficiently thinner than the Cu film) on the substrate 10 side of the Cu film, it is considered that the difference in warping amount occurring between the example and the comparative example depends on the thickness and internal stress of the Cu film and the SiN film.

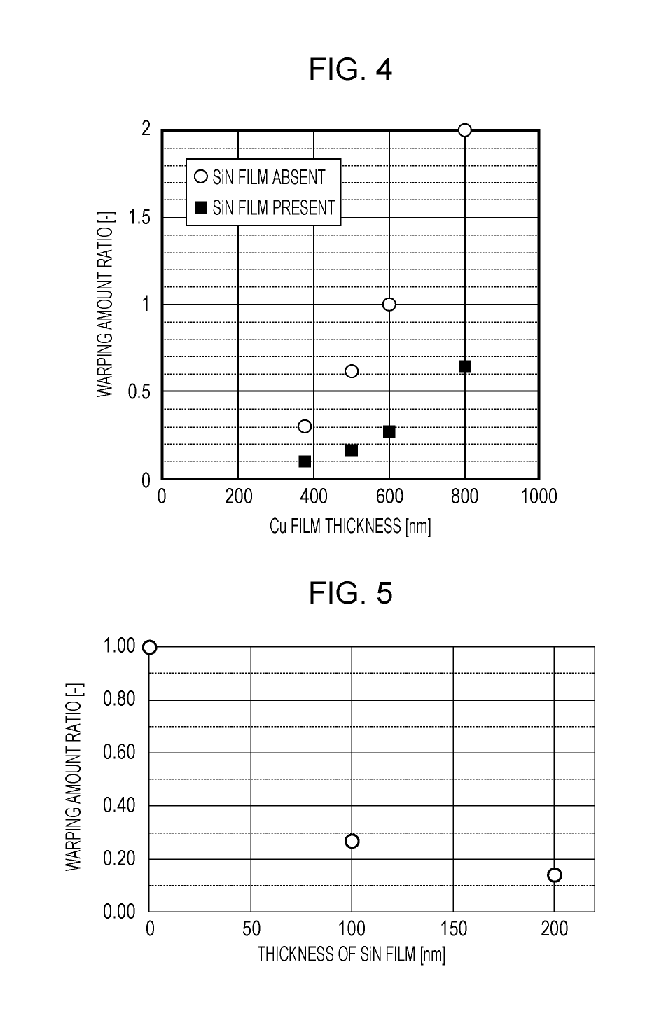

FIG. 4 is a diagram showing the relationship between the thickness of a Cu film and the warping amount in the sample substrates 100A and 100B of the example and the comparative example. Here, FIG. 4 shows changes in the warping amount of the sample substrates of the example and comparative example in a case where the thickness of the inorganic insulating layer 30 is set to 100 nm and the thickness of the Cu film is changed from 400 nm to 800 nm. The warping amount on the vertical axis is expressed as a ratio (warping amount ratio) to the warping amount of the sample substrate (thickness of the Cu film: 600 nm) of the comparative example.

From this result, it is understood that the warping amount increases as the thickness of the metal film 120 formed on the substrate 10 increases. In addition, it is understood that providing the inorganic insulating layer 30 (here, the SiN film) makes it possible for the warping amount when the thickness of the Cu film is 500 nm or more to be reduced to ⅓ or less.

FIG. 5 is a diagram showing the relationship between the thickness of the inorganic insulating layer 30 and the warping amount in the sample substrates 100A and 100B of the example and the comparative example. Here, FIG. 5 shows changes in the warping amount when the thickness of the Cu film is set to 500 nm and the thickness of the inorganic insulating layer 30 (SiN film) is 0 nm (comparative example), 100 nm, and 200 nm.

As understood from FIG. 5, by providing a SiN film having a thickness of 100 nm, the warping amount is reduced to ⅓ or less, and, by providing a SiN film having a thickness of 200 nm, the warping amount is reduced to ⅕ or less. Accordingly, it is understood that increasing the thickness of the inorganic insulating layer 30 makes it possible to more effectively reduce the warping amount.

Here, although the Cu film is used as the metal film 120, the same tendency is seen even when an Al film is used. Furthermore, it is sufficient if the inorganic insulating layer 30 also has a prescribed compressive stress and the material thereof is not particularly limited.

Next, in the example and comparative example, the stress values of the inorganic insulating layer 30 and the metal film 120 of the sample substrates 100A and 100B were calculated. Based on the thickness of the substrate 10, the Poisson's ratio, the Young's modulus, the measured warping amount, the length of the portion where warping occurred, and the thickness of the thin film (SiN film or Cu/Ti film), the stress values were calculated using Stoney's equation. In this example, the metal film 120 has tensile stress and the inorganic insulating layer 30 has compressive stress.

The calculation results of the stress value are shown in Table 1.

TABLE 1

| | Thickness [nm] | Stress value [MPa] |
|---|---|---|
| Metal film (Cu/Ti) | Cu: 375, Ti: 35 | 381 |
| | Cu: 500, Ti: 35 | 467 |
| | Cu: 600, Ti: 35 | 536 |
| | Cu: 700, Ti: 35 | 604 |
| | Cu: 800, Ti: 35 | 673 |
| Inorganic insulating | 100 | 350 |
| layer (SiN) | 200 | 700 |

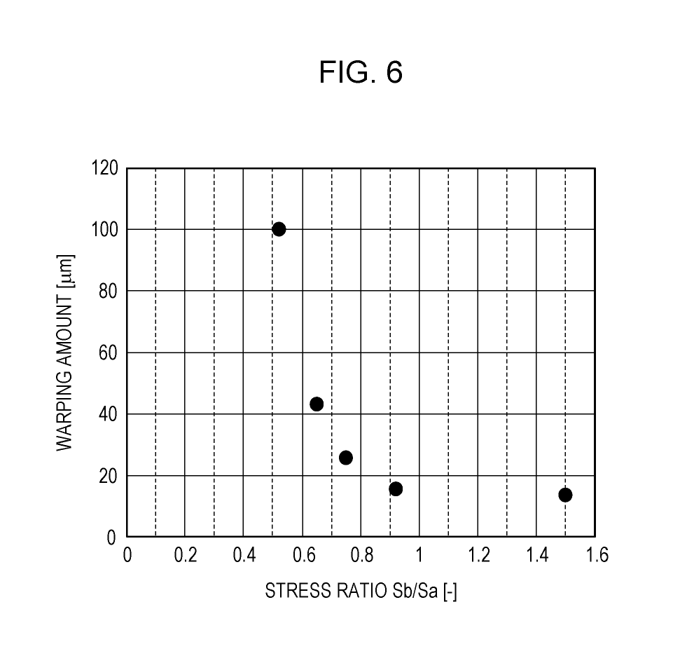

FIG. 6 is a diagram showing the relationship between the ratio (referred to below as “stress ratio”) Sb/Sa of the absolute value Sb of compressive stress of the inorganic insulating layer 30 to the absolute value Sa of tensile stress of the metal film 120, and the warping amount (μm).

From this result, it is understood that, if the stress ratio Sb/Sa is, for example, 0.6 or more, and preferably 0.7 or more, it is possible to sufficiently reduce the warping amount and to suppress a decrease in mass productivity. On the other hand, when the stress ratio Sb/Sa is excessively large, it may not be possible to sufficiently reduce the resistance of the metal wire, or the thickness of the SiN film may increase, making it difficult to miniaturize the device. From this viewpoint, the stress ratio Sb/Sa is, for example, preferably 1.7 or less, and more preferably 1.5 or less.

As described above, according to the present embodiment, forming the metal wiring layer 20 on the inorganic insulating layer 30 makes it possible to form a low-resistance metal wire formed of a thick metal film even in a case where a comparatively thin glass substrate is used as a support substrate. Additionally, since the inorganic insulating layer 30 may be formed so as to have a prescribed compressive stress according to the stress value of the metal film, the material of the metal wire, the manufacturing process, and the thickness are also highly flexible.

### <Control of Stress Value of Inorganic Insulating Layer 30>

It is possible for the stress value of the inorganic insulating layer 30 to be controlled according to the material, thickness, process conditions, and the like of the inorganic insulating layer 30. In the present embodiment, the material, thickness, process conditions, and the like of the inorganic insulating layer 30 are configured such that the inorganic insulating layer 30 has a compressive stress which is able to relieve the tensile stress of the metal wiring layer 20.

A description will be given of a method of forming the inorganic insulating layer 30 taking a silicon nitride (SiN) layer as an example. It is possible to form the SiN layer by a plasma CVD method using, for example, a mixed gas including SiH₄, NH₃, and N₂. Although the forming conditions are not particularly limited, for example, the flow rate ratio SiH₄/NH₃/N₂ in the source gas may be set to 100 to 500/100 to 1000/1000 to 6000 sccm, the pressure may be set to 100 to 300 Pa, and the RF power may be set to 200 to 4000 W. These conditions and the thickness of the SiN film are appropriately configured so as to obtain a desired compressive stress.

For example, as is understood from the above example, the compressive stress increases as the thickness of the SiN film is increased.

In addition, adjusting the flow rate ratio of the source gas makes it possible to change the stress value of the SiN film. For example, when the flow rate of SiH₄ is increased, the stress value of the compressive stress increases. On the other hand, when the substrate temperature and the gas pressure are increased, the compressive stress decreases (there may be a tensile stress) (refer to Japanese Journal of Applied Physics Vol. 44, No. 6A, 2005, p. 4098-4102). Furthermore, it is also possible to increase the compressive stress of the SiN film, for example, by decreasing the flow rate ratio NH₃/SiH₄ of NH₃ with respect to SiH₄ in the source gas, or by adding hydrogen gas to the source gas (Japanese Unexamined Patent Application Publication No. 2009-152293). Furthermore, it is possible to change the internal stress of the SiN film by changing the nitrogen gas flow rate (refer to International Publication No. 2011/043297).

### <Arrangement Example of Metal Wiring Layer 20>

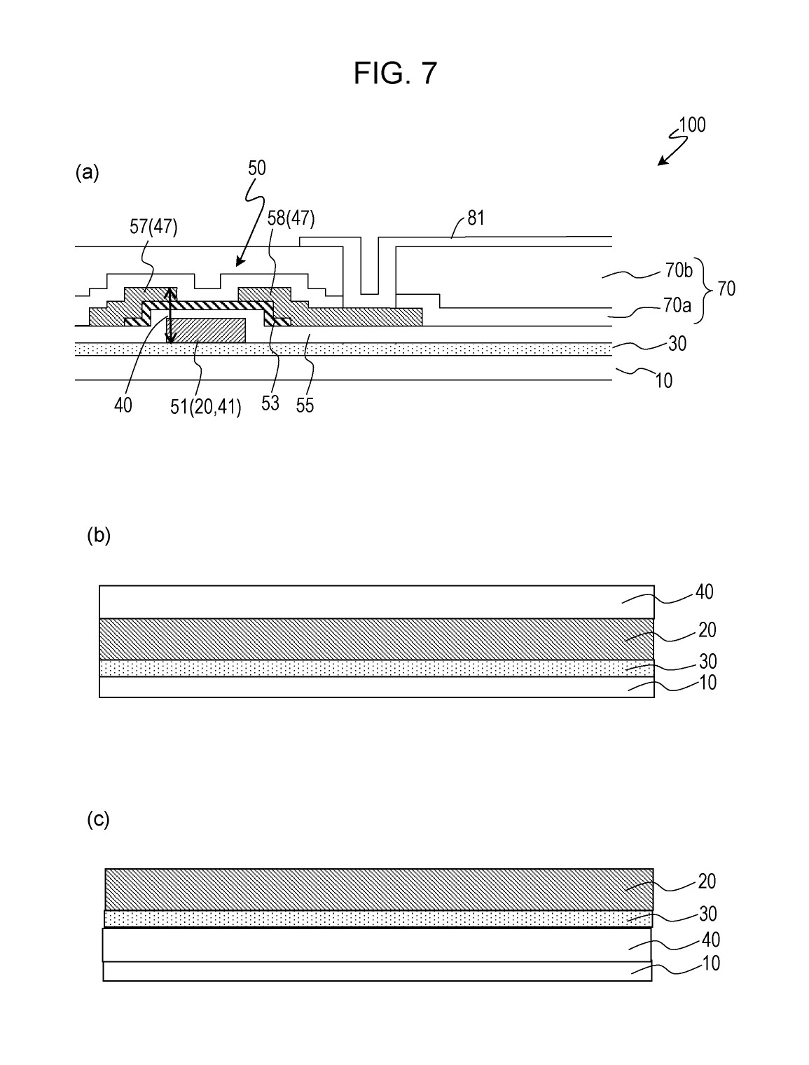

FIGS. 7(a) to 7(c) are schematic cross-sectional views each illustrating the arrangement relationship between the metal wiring layer 20 and the TFT-containing layer 40 in the present embodiment. In the example shown in FIG. 7(a), the metal wiring layer 20 is a gate electrode layer in the TFT-containing layer 40. In the examples shown in FIGS. 7(b) and 7(c), the metal wiring layer 20 is a layer different from the TFT-containing layer 40. For simplicity, the constituent elements in the TFT-containing layer 40 are not shown in FIGS. 7(b) and 7(c).

The active matrix substrate 100 has a display region including a plurality of pixel regions arranged in a matrix shape. FIG. 7(a) shows one pixel region in the display region.

In the example shown in FIG. 7(a), each pixel region has the inorganic insulating layer 30 formed on the substrate 10, a TFT (pixel TFT) 50 formed on the inorganic insulating layer 30, an interlayer insulating layer 70 covering the TFT 50, and a pixel electrode 81 provided on the interlayer insulating layer 70. The TFT 50 has a gate electrode 51, a semiconductor layer (here, for example, an oxide semiconductor layer) 53, a gate insulating layer 55 arranged between the semiconductor layer 53 and the gate electrode 51, and a source electrode 57 and a drain electrode 58 electrically connected to the semiconductor layer 53. In this example, the interlayer insulating layer 70 includes a lower layer (passivation film) 70a formed of an inorganic insulating film, and an upper layer 70b formed of an organic insulating film. The drain electrode 58 is connected to the pixel electrode 81 in a contact hole formed in the interlayer insulating layer 70. Although not shown, the gate electrode 51 is connected to a gate wire, and the source electrode 57 is connected to a source wire. The gate wire and the gate electrode 51 are formed from the same conductive film, and the source wire and the source electrode 57 are formed from the same conductive film.

In this example, when a layer formed from the same conductive film as the gate electrode 51 is a gate electrode layer 41 and a layer formed from the same conductive film as the source electrode 57 is a source electrode layer 47, the gate electrode layer 41, the source electrode layer 47, and a layer positioned between these wiring layers form the TFT-containing layer 40. Additionally, the gate electrode layer 41 corresponds to the metal wiring layer 20 and, for example, the gate wire corresponds to the metal wire 21 (FIG. 1). That is, the gate electrode layer 41 (the gate electrode 51 and the gate wire) is formed of a metal film having a thickness of 500 nm or more.

In the example shown in FIG. 7(b), the metal wiring layer 20 is arranged between the TFT-containing layer 40 and the substrate 10. Here, the inorganic insulating layer 30, the metal wiring layer 20 and the TFT-containing layer 40 are formed in this order on the substrate 10. The configuration of the TFT-containing layer 40 is the same as that of FIG. 7(a), for example. The metal wiring layer 20 may include a source wire or a gate wire electrically connected to the source electrode or the gate electrode of the TFT. Alternatively, the metal wiring layer 20 may include other wires (broadly including driving wires, connection wires, and the like). In addition to the wire or in place of the wire, the metal wiring layer 20 may include a light shielding layer for suppressing the incidence of light from the substrate 10 side to the TFT, the light-receiving element, and the like arranged on the active matrix substrate. Although not shown, a planarization layer may be provided on the metal wiring layer 20 in order to reduce the unevenness of the metal wire and the electrodes in the metal wiring layer 20.

As shown in FIG. 7(c), the metal wiring layer 20 may be arranged above the TFT-containing layer 40 with the inorganic insulating layer 30 interposed therebetween. The metal wiring layer 20 may include a source wire or a gate wire electrically connected to the source electrode or the gate electrode of the TFT. Alternatively, the metal wiring layer 20 may include other wires (a driving wire, a connection wire, and the like).

In the present embodiment, it is possible to obtain a more remarkable effect in a case where the metal wiring layer 20 is formed prior to the TFT 50. That is, the metal wiring layer 20 is preferably provided on the substrate 10 side of the TFT-containing layer 40 (FIG. 7(b)) or the lowermost layer (for example, the gate electrode layer) of the TFT 50 (FIG. 7(a)). In such a case, since the metal wiring layer 20 is formed prior to the TFT 50, the electric resistance of the metal wire 21 may increase due to the thermal process when the TFT 50 is formed. In the present embodiment, since it is possible to form the metal wire 21 to be thicker in consideration of an increase in electric resistance due to the thermal process, it is possible to realize a lower resistance in the metal wire 21.

In the TFT 50 illustrated in FIG. 7(a), the gate electrode 51 is arranged on the substrate 10 side of the semiconductor layer 53 (bottom gate structure); however, the gate electrode 51 may be arranged above the semiconductor layer 53 (top gate structure). In addition, the TFT 50 in the embodiment described above may have a channel-etch structure or may have an etch-stop structure having an etch-stop covering the channel region. Furthermore, the TFT 50 may have a top contact structure in which the source and drain electrodes are in contact with the upper surface of the semiconductor layer, or a bottom contact structure in which the source and drain electrodes are in contact with the lower surface of the semiconductor layer. The semiconductor layer 53 is not particularly limited and may be an amorphous silicon layer, a polysilicon layer, a microcrystalline silicon layer, an oxide semiconductor layer, or the like.

In the following embodiments, a description will be given of a more specific configuration of an active matrix substrate with reference to the drawings.

### Second Embodiment

The active matrix substrate of the second embodiment is provided with a scanning wire which supplies a scanning signal to a gate electrode, using a conductive film different from the gate electrode of the pixel TFT, between the pixel TFT and the substrate. Such a configuration is also described in PTL 1 and the like by the present applicant. For reference, all of the disclosed content of PTL 1 is incorporated into the present specification.

In the present embodiment, the scanning wire described above is formed on the support substrate with an inorganic insulating layer which is a stress relieving layer interposed therebetween. With this, even in a case where a thin glass substrate is used as the support substrate, it is possible to form a scanning wire having lower resistance than in the related art while suppressing warping of the glass substrate.

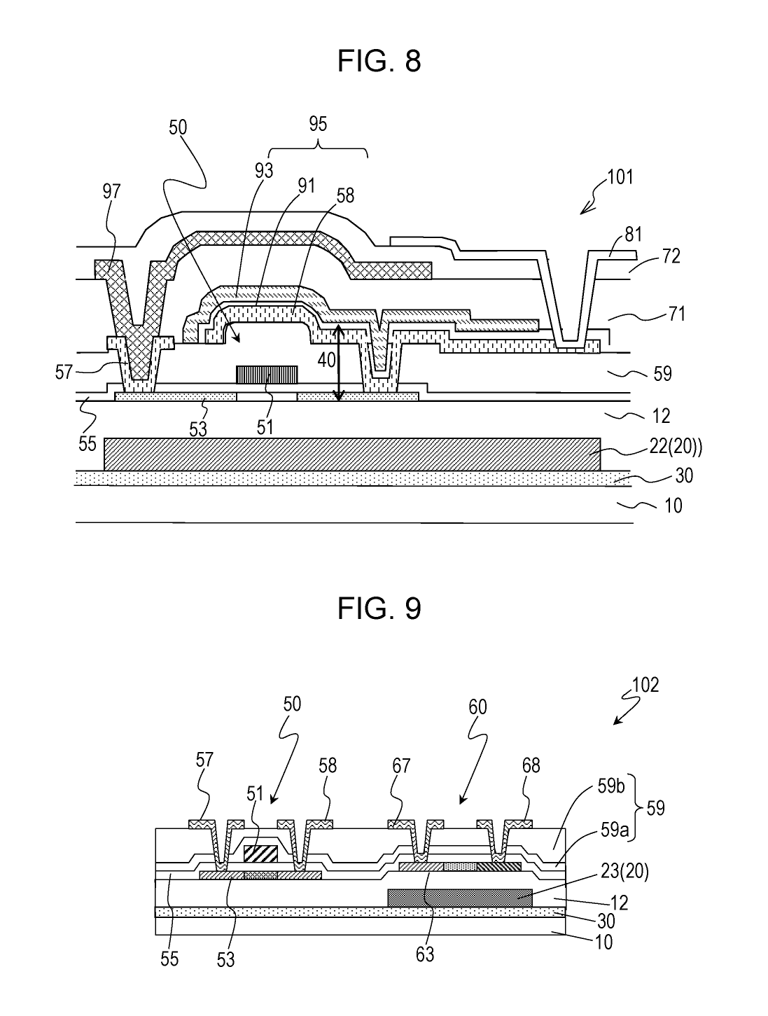

FIG. 8 is a schematic cross-sectional view of the active matrix substrate 101 of the second embodiment.

The active matrix substrate 101 has the substrate (for example, a glass substrate) 10 having an insulating property, the inorganic insulating layer 30 formed on the substrate 10, and the metal wiring layer 20 including a scanning wire (corresponding to the metal wire 21 in FIG. 1) 22 formed on the inorganic insulating layer 30. In this example, the scanning wire 22 also functions as a light shielding film. Since the substrate 10, the inorganic insulating layer 30, the metal wiring layer 20, and the scanning wire 22 are formed using the same materials as those of the embodiment described above and have the same configurations, a detailed description thereof will be omitted.

The scanning wire 22 is covered with a first interlayer insulating layer 12. The first interlayer insulating layer 12 may be an inorganic insulating layer. The first interlayer insulating layer 12 may be a silicon oxide film or a silicon nitride film, or a planarization film formed of a Spin On Glass (SOG) film. In particular, when the stress ratio Sb/Sa is 1 or less, it is possible to more effectively reduce warping of the substrate 10 when a silicon oxide film, a silicon nitride film, or an SOG film having compressive stress is formed as the first interlayer insulating layer 12. As the first interlayer insulating layer 12, a silicon nitride film and an SOG film may be formed in this order.

On the first interlayer insulating layer 12, the TFT-containing layer 40 including the TFT 50 is formed. In this example, the TFT 50 has a top gate structure. The TFT-containing layer 40 has a semiconductor layer (here, for example, a polysilicon layer) 53 formed on the first interlayer insulating layer 12, the gate insulating layer 55 covering the semiconductor layer 53, and the gate electrode 51 arranged on the gate insulating layer 55, a second interlayer insulating layer 59 covering the gate electrode 51, and the source electrode 57 and the drain electrode 58 provided on the second interlayer insulating layer 59. The semiconductor layer 53 has a channel region and source and drain regions arranged on both sides of the channel region and having lower resistance than the channel region. The source electrode 57 is connected to the source region of the semiconductor layer 53 in a contact hole formed in the gate insulating layer 55 and the second interlayer insulating layer 59. The drain electrode 58 is connected to the drain region of the semiconductor layer 53 in a contact hole formed in the gate insulating layer 55 and the second interlayer insulating layer 59. Additionally, although not shown, the gate electrode 51 is connected to the scanning wire 22 in a contact hole formed in the inorganic insulating layer 30.

A capacitance element 95 is formed on the TFT 50. Specifically, a capacitance dielectric film 91 and a second capacitance electrode 93 are formed on the drain electrode 58 in this order from the substrate 10 side. The capacitance element 95 is formed of the capacitance dielectric film 91 and the drain electrode (also referred to as a first capacitance electrode) 58 and the second capacitance electrode 93 which face each other with the capacitance dielectric film 91 interposed therebetween. The first capacitance electrode 58 is a conductive layer formed separately for each pixel and the second capacitance electrode 93 is a part of a capacitor wire extending substantially in parallel with the scanning wire 22. The capacitance element 95 is overlaid on the channel region of the TFT 50 when viewed from the substrate normal direction. At least one of the first capacitance electrode 58 and the second capacitance electrode 93 is formed of a material having a light shielding property and is also able to function as a light shielding layer.

A third interlayer insulating layer 71 is formed so as to cover the capacitance element 95. A signal wire 97 is formed on the third interlayer insulating layer 71. The signal wire 97 is connected to the source electrode 57 in a contact hole formed in the third interlayer insulating layer 71 and the second interlayer insulating layer 59. The pixel electrode 81 is provided over the signal wire 97 and the third interlayer insulating layer 71 with the fourth interlayer insulating layer 72 interposed therebetween. The pixel electrode 81 is connected to the first capacitance electrode (drain electrode) 58 in a contact hole formed in the capacitance dielectric film 91, the third interlayer insulating layer 71, and the fourth interlayer insulating layer 72.

In the active matrix substrate 101 of the present embodiment, even when the comparatively thin substrate 10 is used, it is possible to form the scanning wire 22 having lower resistance than in the related art while suppressing warping of the substrate 10. In addition, covering the metal wiring layer 20 with the first interlayer insulating layer 12 makes it possible to more effectively reduce warping and to improve the yield.

The structures of the TFT 50, the capacitance element 95, and other electrodes and wires are not limited to the illustrated examples. For example, as disclosed in Japanese Unexamined Patent Application Publication No. 2008-26766, the scanning wire may be formed in the same layer as the gate electrode, and the light shielding film of the TFT 50 may be formed in the metal wiring layer 20. The light shielding film may be electrically connected to a constant potential wire.

### Third Embodiment

The active matrix substrate of the third embodiment includes a photosensor unit. The photosensor unit includes a thin film diode (TFD) formed using a semiconductor film (here, a polysilicon film) common to the pixel TFT as a light-receiving element. A configuration of an active matrix substrate provided with a photosensor unit is disclosed in, for example, International Publication No. 2008/132862. For reference, all the disclosures of the above PTLs are incorporated in the present specification.

In the present embodiment, there is a light shielding layer formed of a metal film on the substrate side of the TFD. The light shielding layer is formed on the substrate with an inorganic insulating layer which is a stress relieving layer interposed therebetween.

FIG. 9 is a schematic cross-sectional view of the active matrix substrate 102 of the third embodiment.

The active matrix substrate 102 is provided with the substrate 10, the inorganic insulating layer 30 arranged on the substrate 10, and the metal wiring layer 20 formed on the inorganic insulating layer 30 and including a light shielding layer 23. The metal wiring layer 20 is covered with the first interlayer insulating layer 12. Since the substrate 10, the inorganic insulating layer 30, the metal wiring layer 20, and the first interlayer insulating layer 12 are formed using the same materials as those in the embodiment described above and have the same configuration, a detailed explanation thereof will be omitted.

The TFT-containing layer 40 including the TFT 50 and a TFD 60 is formed on the metal wiring layer 20. Although not shown, a pixel electrode is provided on the TFT-containing layer 40. The light shielding layer 23 is arranged so as to overlap the TFD 60 when viewed from the normal direction of the substrate 10. In a case of forming the semiconductor layer (polysilicon layer) 53 by crystallizing an amorphous silicon film, in the crystallization step, the light shielding layer 23 is also able to function as a heat sink layer during laser irradiation.

The TFT 50 has the semiconductor layer 53 including a channel region, a source region, and a drain region, the gate insulating layer 55 provided over the semiconductor layer 53, the gate electrode 51 for controlling the conductivity of the channel region, the second interlayer insulating layer 59 covering the gate electrode 51, and the source electrode 57 and the drain electrode 58 provided on the second interlayer insulating layer 59. The source electrode 57 and the drain electrode 58 are respectively connected to the source region and the drain region of the semiconductor layer 53 in an opening formed in the second interlayer insulating layer 59. In this example, the second interlayer insulating layer 59 includes a lower layer 59a formed of an inorganic insulating film (passivation film) and an upper layer 59b formed of an organic insulating film.

The TFD 60 has a semiconductor layer 63 including at least an n-type region and a p-type region, the gate insulating layer 55 and the second interlayer insulating layer 59 extending over the semiconductor layer 63, and electrodes and wires 67 and 68 which are provided on the second interlayer insulating layer 59. The electrodes and wires 67 and 68 are respectively connected to the n-type region and the p-type region of the semiconductor layer 63 in the opening formed in the second interlayer insulating layer 59. In the illustrated example, an intrinsic region is provided between the n-type region and the p-type region in the semiconductor layer 63.

In the active matrix substrate 102 of the present embodiment, even when a comparatively thin glass substrate is used as the substrate 10, it is possible to form a light shielding layer (or a heat sink layer) 23 using a thicker metal film than in the related art while suppressing warping of the substrate 10. Additionally, covering the metal wiring layer 20 with the first interlayer insulating layer 12 makes it possible to more effectively reduce the warping and to improve the yield.

### Fourth Embodiment

The active matrix substrate of the fourth embodiment is a photodetector apparatus provided with a photodiode. Such an active matrix substrate is disclosed in, for example, PTL 2, International Publication No. 2015/141777 by the present applicant, and the like.

In the present embodiment, a metal wiring layer including a source wire and a bias wire is provided on a TFT-containing layer with an inorganic insulating layer functioning as a stress relieving layer interposed therebetween.

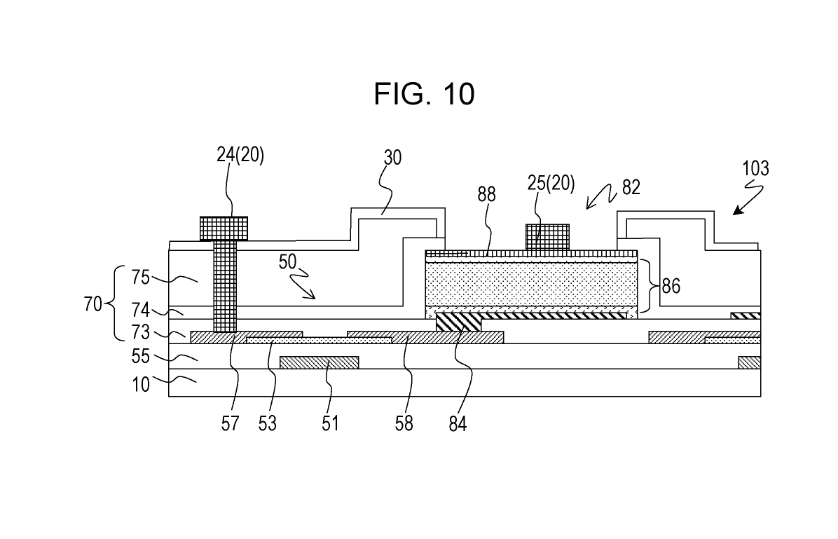

FIG. 10 is a schematic cross-sectional view of the active matrix substrate (photodetector apparatus) 103 of the present embodiment.

The active matrix substrate 103 has the substrate 10 and the TFT 50 and a photodiode 82 supported on the substrate 10.

The TFT 50 has the gate electrode 51, the gate insulating layer 55 covering the gate electrode 51, the semiconductor layer (for example, an oxide semiconductor layer) 53 formed on the gate insulating layer 55, and the source electrode 57 and the drain electrode 58 connected to the semiconductor layer 53. The TFT 50 is covered with the interlayer insulating layer 70 and the inorganic insulating layer 30. In this example, the interlayer insulating layer 70 includes a first passivation film 73, a second passivation film 74, and a planarization film 75. On the interlayer insulating layer 70, the metal wiring layer 20 including a source wire 24 is formed with the inorganic insulating layer 30 interposed therebetween. The substrate 10, the inorganic insulating layer 30, and the metal wiring layer 20 are formed using the same materials as in the embodiment described above and have the same configuration.

The photodiode 82 is arranged in the opening of the interlayer insulating layer 70. The photodiode 82 has a lower electrode 84 electrically connected to the drain electrode 58, a semiconductor laminated structure 86, and an upper electrode 88. A bias wire 25 is formed on the upper electrode 88. The bias wire 25 extends, for example, in parallel to the source wire 24 so as to cut across a plurality of pixels. The bias wire 25 is formed using the same metal film as the source wire 24 (that is, in the metal wiring layer 20).

The photodiode 82 converts light irradiated on the semiconductor laminated structure 86 into electrical charges (electrons or holes). When a voltage is applied between the bias wire 25 and the drain electrode 58 such that the semiconductor laminated structure 86 is in a reverse bias state, the light irradiated to the semiconductor laminated structure 86 is converted into an excited electrical charge in a depletion layer. The electrical charge generated by the photodiode 82 is taken to the outside via the source wire 24 by setting the TFT 50 connected to the photodiode 82 to an on state. In this manner, it is possible to convert the irradiation amount of the light irradiated on the semiconductor laminated structure 86 into a current amount and output the current as an electric signal or an image.

Embodiments of the present invention are not limited to the illustrated active matrix substrates 101 to 103. It is possible to apply embodiments of the present invention to various active matrix substrates manufactured by forming the inorganic insulating layer 30 and then forming the metal wiring layer 20 including electrodes, wires, and the like so as to be in contact with the inorganic insulating layer 30.

### <TFT Structure and Oxide Semiconductor>

The TFT 50 in the embodiment of the present invention may have a channel-etch structure or may have an etch-stop structure.

In the “channel-etch type TFT”, for example, as shown in FIG. 7(a), no etch-stop layer is formed on the channel region and the lower surfaces of the end portions of the source and drain electrodes on the channel side are arranged so as to be in contact with the upper surface of the semiconductor layer. The channel-etch type TFT is formed by, for example, forming a conductive film for source and drain electrodes on a semiconductor layer and performing source and drain separation. In the source and drain separation step, the surface portion of the channel region may be etched.

On the other hand, in the TFT (etch-stop type TFT) in which the etch-stop layer is formed on the channel region, the lower surfaces of the end portions of the source and drain electrodes on the channel side are positioned, for example, on the etch-stop layer. An etch-stop type TFT is formed by, for example, forming an etch-stop layer covering a portion to be a channel region in a semiconductor layer, then forming a conductive film for a source and drain electrode on a semiconductor layer and an etch-stop layer, and performing a source and drain separation.

The TFT 50 may be an oxide semiconductor TFT having an oxide semiconductor layer as the semiconductor layer 53. The oxide semiconductor included in the oxide semiconductor layer may be an amorphous oxide semiconductor or a crystalline oxide semiconductor having a crystalline portion. Examples of the crystalline oxide semiconductor include a polycrystalline oxide semiconductor, a microcrystalline oxide semiconductor, a crystalline oxide semiconductor in which the c-axis is oriented substantially perpendicularly to the layer surface, and the like.

The oxide semiconductor layer may have a laminated structure of two or more layers. In a case where the oxide semiconductor layer has a laminated structure, the oxide semiconductor layer may include an amorphous oxide semiconductor layer and a crystalline oxide semiconductor layer. Alternatively, a plurality of crystalline oxide semiconductor layers having different crystal structures may be included. In addition, a plurality of amorphous oxide semiconductor layers may be included. In a case where the oxide semiconductor layer has a two-layer structure including an upper layer and a lower layer, the energy gap of the oxide semiconductor included in the upper layer is preferably larger than the energy gap of the oxide semiconductor included in the lower layer. However, in a case where the difference in energy gap between these layers is comparatively small, the energy gap of the lower layer oxide semiconductor may be larger than the energy gap of the upper layer oxide semiconductor.

The material, structure, film formation method, configuration of an oxide semiconductor layer having a laminated structure, and the like of the amorphous oxide semiconductor and each of the crystalline oxide semiconductors described above are described in, for example, Japanese Unexamined Patent Application Publication No. 2014-007399. For reference, all the disclosed content of Japanese Unexamined Patent Application Publication No. 2014-007399 is incorporated in the present specification.

The oxide semiconductor layer may include, for example, at least one kind of metal element selected from In, Ga, and Zn. In the present embodiment, the oxide semiconductor layer includes, for example, an In-Ga-Zn-O-based semiconductor (for example, indium gallium zinc oxide). Here, the In-Ga-Zn-O-based semiconductor is a ternary oxide of In (indium), Ga (gallium), Zn (zinc), and the ratio of In, Ga and Zn (composition ratio) is not particularly limited and includes, for example, In:Ga:Zn=2:2:1, In:Ga:Zn=1:1:1, In:Ga:Zn=1:1:2, and the like. It is possible to form such an oxide semiconductor layer from an oxide semiconductor film including an In-Ga-Zn-O-based semiconductor.

The In-Ga-Zn-O-based semiconductor may be amorphous or crystalline. As a crystalline In-Ga-Zn-O-based semiconductor, a crystalline In-Ga-Zn-O-based semiconductor in which the c-axis is oriented substantially perpendicular to the layer surface is preferable.

The crystal structure of a crystalline In-Ga-Zn-O-based semiconductor is disclosed in, for example, Japanese Unexamined Patent Application Publication No. 2014-007399, Japanese Unexamined Patent Application Publication No. 2012-134475, Japanese Unexamined Patent Application Publication No. 2014-209727, and the like. For reference, all of the disclosure content of Japanese Unexamined Patent Application Publication No. 2012-134475 and Japanese Unexamined Patent Application Publication No. 2014-209727 is incorporated in the present specification. Since a TFT having an In-Ga-Zn-O-based semiconductor layer has high mobility (more than 20 times in comparison with that of an a-Si TFT) and low leak current (less than 1/100th in comparison with an a-Si TFT), such a TFT may be suitably used as a driving TFT (for example, a TFT included in a driving circuit provided on the same substrate as a display region in the periphery of a display region including a plurality of pixels) and as a pixel TFT (TFT provided in a pixel).

Instead of the In-Ga-Zn-O-based semiconductor, the oxide semiconductor layer may include another oxide semiconductor. For example, the oxide semiconductor layer may include an In-Sn-Zn-O-based semiconductor (for example, In₂O₃—SnO₂—ZnO; InSnZnO). The In-Sn-Zn-O-based semiconductor is a ternary oxide of In (indium), Sn (tin), and Zn (zinc). Alternatively, the oxide semiconductor layer may include an In-Al-Zn-O based semiconductor, an In-Al-Sn-Zn-O based semiconductor, a Zn-O based semiconductor, an In-Zn-O based semiconductor, a Zn-Ti-O based semiconductor, a Cd-Ge-O based semiconductor, a Cd-Pb-O based semiconductor, CdO (cadmium oxide) based semiconductor, a Mg-Zn-O based semiconductor, an In-Ga-Sn-O based semiconductor, an In-Ga-O based semiconductor, a Zr-In-Zn-O based semiconductor, an Hf-In-Zn-O based semiconductor, an Al-Ga-Zn-O based semiconductor, a Ga-Zn-O based semiconductor, and the like.

### INDUSTRIAL APPLICABILITY

Embodiments of the present invention may be broadly applied to various apparatus provided with an active matrix substrate, for example, a liquid crystal display apparatus, an organic electroluminescence (EL) display apparatus, a display apparatus using inorganic electroluminescence or the like, an in-cell touch panel type display apparatus, an image capturing apparatus such as an image sensor apparatus, an apparatus provided with a thin film transistor such as an electronic apparatus such as an image input apparatus or a fingerprint reading device.

### REFERENCE SIGNS LIST

10 SUBSTRATE

12 FIRST INTERLAYER INSULATING LAYER

20 METAL WIRING LAYER

20a FIRST METAL FILM

20b SECOND METAL FILM

21 METAL WIRE

22 SCANNING WIRE

23 LIGHT SHIELDING LAYER

24 SOURCE WIRE

25 BIAS WIRE

30 INORGANIC INSULATING LAYER (STRESS RELIEVING LAYER)

40 TFT-CONTAINING LAYER

41 GATE ELECTRODE LAYER

47 SOURCE ELECTRODE LAYER

51 GATE ELECTRODE

53 SEMICONDUCTOR LAYER

55 GATE INSULATING LAYER

57 SOURCE ELECTRODE

58 DRAIN ELECTRODE

81 PIXEL ELECTRODE

100, 101, 102, 103 ACTIVE MATRIX SUBSTRATE

100A, 100B SAMPLE SUBSTRATE

120 METAL FILM

1. An active matrix substrate having a display region including a plurality of pixels, each of the plurality of pixels having a TFT and a pixel electrode, the active matrix substrate comprising:
a substrate;
a TFT-containing layer which is supported on the substrate, and which includes a gate electrode, a gate insulating layer, a semiconductor layer, and source and drain electrodes of the TFT;
a metal wiring layer which is supported on the substrate and has a thickness of 400 nm or more; and
an inorganic insulating layer which is thinner than the metal wiring layer, and is arranged on a substrate side of the metal wiring layer and is in contact with a lower surface of the metal wiring layer, wherein
the metal wiring layer has tensile stress and the inorganic insulating layer has compressive stress, and
a ratio of an absolute value Sb to an absolute value Sa is 0.6 or more and 1.7 or less, the absolute value Sb being a stress value of the inorganic insulating layer, the absolute value Sa being a stress value of the metal wiring layer.

2. The active matrix substrate according to claim 1, wherein
the ratio of the absolute value Sb to the absolute value Sa is 0.7 or more and 1.5 or less.

3. The active matrix substrate according to claim 1, wherein
a thickness of the metal wiring layer is 500 nm or more.

4. The active matrix substrate according to claim 1, wherein
the metal wiring layer includes a wire or an electrode.

5. The active matrix substrate according to claim 4, wherein
the wire extends to cut across the display region.

6. The active matrix substrate according claim 1, wherein
the TFT-containing layer includes the metal wiring layer.

7. The active matrix substrate according to claim 6, wherein
the metal wiring layer includes the gate electrode and a gate wire electrically connected to the gate electrode.

8. The active matrix substrate according claim 1, wherein
the metal wiring layer and the inorganic insulating layer are arranged between the TFT-containing layer and the substrate.

9. The active matrix substrate according to claim 8, further comprising
a planarization layer which is arranged between the metal wiring layer and the TFT-containing layer.

10. The active matrix substrate according claim 1, wherein
the metal wiring layer and the inorganic insulating layer are arranged above the TFT-containing layer.

11. The active matrix substrate according claim 1, wherein
the metal wiring layer includes a Cu layer or an Al layer.

12. The active matrix substrate according to claim 11, wherein
the metal wiring layer further includes a Ti layer or a Mo layer on the substrate side of the Cu layer or the Al layer.

13. The active matrix substrate according claim 1, wherein
the inorganic insulating layer includes a silicon nitride layer.

14. The active matrix substrate according to claim 13, wherein
the silicon nitride layer has a thickness of 50 nm or more and 300 nm or less.

15. The active matrix substrate according claim 1, wherein
the substrate is a glass substrate having a thickness of 0.7 mm or less.

16. The active matrix substrate according claim 1, wherein
the metal wiring layer is a layer obtained by patterning a metal film deposited on the inorganic insulating layer.

17. The active matrix substrate according claim 1, wherein
the TFT is a channel-etch type TFT.

18. The active matrix substrate according claim 1, wherein
the semiconductor layer of the TFT is an oxide semiconductor layer.

19. The active matrix substrate according to claim 18, wherein
the oxide semiconductor layer includes an In-Ga-Zn-O-based semiconductor.
